(19) United States
(12) Patent Application Publication
(10) Pub. No.: US 2026/0172069 A1
(43) Pub. Date: Jun. 18, 2026

(54) SWITCHING TRANSFORMER FOR A CONVERGED POWER AMPLIFIER

(71) Applicant: Skyworks Solutions, Inc., Irvine, CA (US)

(72) Inventors: Ying Chen, Camarillo, CA (US); Jiayu Hong, Camarillo, CA (US); Xiao Ma, Newbury Park, CA (US); Jiunn-Sheng Guo, Eastvale, CA (US)

(21) Appl. No.: 19/416,963

(22) Filed: Dec. 11, 2025

Related U.S. Application Data
(60) Provisional application No. 63/733,119, filed on Dec. 12, 2024.

(51) Int. Cl. H04B 1/40; H01F 27/28; H03F 3/24

(52) U.S. Cl. CPC H04B 1/40; H01F 27/28; H03F 3/245; H03F 2200/451

(57) ABSTRACT

A radio frequency circuit, front-end module and a wireless communication device are disclosed. An example radio frequency circuit assembly comprises a signal contact configured to receive amplified signals, the amplified signals including amplified signals of a first frequency band and amplified signals of a second frequency band, an antenna contact, and a transformer connected in a signal path between the signal contact and the antenna contact, the transformer being switchable between a first configuration and a second configuration, the first configuration having a different turn ratio than the second configuration.

### INCORPORATION BY REFERENCE TO ANY PRIORITY APPLICATIONS

Any and all applications for which a foreign or domestic priority claim is identified in the Application Data Sheet as filed with the present application are hereby incorporated by reference under 37 CFR 1.57.

### BACKGROUND

### Field

Embodiments of this disclosure relate to wireless communication devices, and more particularly to front-end modules for use in radio frequency electronic systems for use across multiple radio frequency bands.

### Description of the Related Technology

A front-end module of a wireless communication device is typically configured to transmit radio frequency (RF) signals. Since multiple RF frequency bands can exist close to each other, the front-end module may be configured to operate across multiple frequency bands. Some front-end modules may be configured to use a single power amplifier to provide amplification for transmitting at multiple RF frequency bands, for example two or more of 2G, 4G, medium high bands (MHB), ultra high band (UHB), and other RF frequency bands. These multiple amplified signals may be at the same power level, or at different power levels. This type of power amplifier is typically referred to as a converged power amplifier. It is desirable to optimize all aspects of such a front-end module for operation across each of the two or more RF frequency bands; however, it is challenging to achieve acceptable load line targets for a respective pair of RF frequency bands (whether at the same power level, or at different power levels). In order to attempt to combat these performance issues, the transformer for the power amplifier output matching network (OMN) may be tuned to improve the performance of one of the RF frequency bands; however, this typically requires a performance trade-off for one or both of the RF frequency bands.

### SUMMARY

According to one embodiment there is provided, a radio frequency circuit assembly comprising a signal contact configured to receive amplified signals, the amplified signals including amplified signals of a first frequency band and amplified signals of a second frequency band, an antenna contact, and a transformer connected in a signal path between the signal contact and the antenna contact, the transformer being switchable between a first configuration and a second configuration, the first configuration having a different turn ratio than the second configuration.

In one example, the radio frequency circuit assembly may further comprise one or more switches coupled to a primary coil of the transformer, the one or more switches being configured to switch the transformer between the first configuration and the second configuration, and the one or more switches being configured to alter the number of turns in the primary coil that are coupled to the signal contact.

In one example, the radio frequency circuit assembly may further comprise one or more switches coupled to a secondary coil of the transformer, the one or more switches being configured to switch the transformer between the first configuration and the second configuration, and the one or more switches being configured to alter the number of turns in the secondary coil that are coupled to the antenna contact.

In one example, the one or more switches are coupled to one or more coil taps of the transformer to alter the number of turns in the coil.

In one example, the one or more switches are configured to alter the number of turns in the coil by selectively connecting a plurality of coils in series to form the primary coil and/or secondary coil of the transformer.

In one example, the radio frequency circuit assembly may further comprise an output matching network that is tuned for the amplified signals of both the first frequency band and the second frequency band.

In one example, the transformer is switchable between three or more different configurations, each configuration having a different turn ratio than the other configurations of the three or more configurations.

According to another embodiment, there is provided a front-end module comprising a power amplifier configured to amplify signals of a first frequency band and signals of a second frequency band, an antenna contact, and a transformer connected in a signal path between the power amplifier and the antenna contact, the transformer being switchable between a first configuration and a second configuration, the first configuration having a different turn ratio than the second configuration.

In one example, the front-end module may further comprise one or more switches coupled to a primary coil of the transformer, the one or more switches being configured to switch the transformer between the first configuration and the second configuration, and the one or more switches being configured to alter the number of turns in the primary coil that are coupled to the power amplifier.

In one example, the front-end module may further comprise one or more switches coupled to a secondary coil of the transformer, the one or more switches being configured to switch the transformer between the first configuration and the second configuration, and the one or more switches being configured to alter the number of turns in the secondary coil that are coupled to the antenna contact.

In one example, the one or more switches are coupled to one or more coil taps of the transformer to alter the number of turns in the coil.

In one example, the one or more switches are configured to alter the number of turns in the coil by selectively connecting a plurality of coils in series to form the primary coil and/or secondary coil of the transformer.

In one example, the front-end module may further comprise an output matching network that is tuned for the amplified signals of both the first frequency band and the second frequency band.

In one example, the transformer is switchable between three or more different configurations, each configuration having a different turn ratio than the other configurations of the three or more configurations.

In one example, the front-end module may further comprise an antenna switch module coupled to the antenna contact.

In one example, the signal contact is a transmit contact and the signal path is a transmit path.

In one example, the power amplifier is a low noise amplifier, the signal contact is a receive contact, and the signal path is a receive path.

According to another embodiment, there is provided a wireless communication device comprising an antenna assembly configured to receive and/or transmit radio frequency signals at both a first frequency band and a second frequency band, a power amplifier configured to amplify signals of the first frequency band and signals of the second frequency band, and a transformer connected in a signal path between the power amplifier and the antenna assembly, the transformer being switchable between a first configuration and a second configuration, the first configuration having a different turn ratio than the second configuration.

In one example, the wireless communication device may further comprise one or more switches coupled to a primary coil of the transformer, the one or more switches being configured to switch the transformer between the first configuration and the second configuration, and the one or more switches being configured to alter the number of turns in the primary coil that are coupled to the power amplifier.

In one example, the wireless communication device may further comprise one or more switches coupled to a secondary coil of the transformer, the one or more switches being configured to switch the transformer between the first configuration and the second configuration, and the one or more switches being configured to alter the number of turns in the secondary coil that are coupled to the antenna contact.

In one example, the one or more switches are coupled to one or more coil taps of the transformer to alter the number of turns in the coil.

In one example, the one or more switches are configured to alter the number of turns in the coil by selectively connecting a plurality of coils in series to form the primary coil and/or secondary coil of the transformer.

In one example, the wireless communication device may further comprise an output matching network that is tuned for the amplified signals of both the first frequency band and the second frequency band.

In one example, the transformer is switchable between three or more different configurations, each configuration having a different turn ratio than the other configurations of the three or more configurations.

In one example, the wireless communication device may further comprise an antenna switch module coupled to the antenna contact.

In one example, the signal contact is a transmit contact and the signal path is a transmit path.

In one example, the power amplifier is a low noise amplifier, the signal contact is a receive contact, and the signal path is a receive path.

Still other aspects, embodiments, and advantages of these exemplary aspects and embodiments are discussed in detail below. Embodiments disclosed herein may be combined with other embodiments in any manner consistent with at least one of the principles disclosed herein, and references to “an embodiment,” “some embodiments,” “an alternate embodiment,” “various embodiments,” “one embodiment” or the like are not necessarily mutually exclusive and are intended to indicate that a particular feature, structure, or characteristic described may be included in at least one embodiment. The appearances of such terms herein are not necessarily all referring to the same embodiment.

For purposes of summarizing the disclosure, certain aspects, advantages and novel features of the innovations have been described herein. It is to be understood that not necessarily all such advantages may be achieved in accordance with any particular embodiment. Thus, the innovations may be embodied or carried out in a manner that achieves or optimizes one advantage or group of advantages as taught herein without necessarily achieving other advantages as may be taught or suggested herein.

### BRIEF DESCRIPTION OF THE DRAWINGS

Various aspects of at least one embodiment are discussed below with reference to the accompanying figures, which are not intended to be drawn to scale. The figures are included to provide illustration and a further understanding of the various aspects and embodiments, and are incorporated in and constitute a part of this specification, but are not intended as a definition of the limits of the invention. In the figures, each identical or nearly identical component that is illustrated in various figures is represented by a like numeral. For purposes of clarity, not every component may be labeled in every figure. In the figures:

FIG. 1 is an example block diagram of a front-end module for a radio frequency communications device;

FIG. 2 is an example block diagram of a front-end module for a radio frequency communications device having a primary coil switching balun;

FIG. 3a is an example smith chart of the loading impedance and impedance for the configurations of FIGS. 1 and 2 when processing example 2G signals;

FIG. 3b is an example smith chart of the loading impedance and impedance for the configurations of FIGS. 1 and 2 when processing example 4G signals;

FIG. 4a is an example plot of insertion loss over signal frequency for the configurations of FIGS. 1 and 2 when processing example 2G signals;

FIG. 4b is an example plot of insertion loss over signal frequency for the configurations of FIGS. 1 and 2 when processing example 4G signals;

FIG. 5 is an example block diagram of a front-end module for a radio frequency communications device having a primary coil multi switching balun;

FIG. 6 is an example block diagram of a front-end module for a radio frequency communications device having a secondary coil switching balun;

FIG. 7a is an example smith chart of the loading impedance and impedance for the configurations of FIGS. 1 and 6 when processing example 2G signals;

FIG. 7b is an example smith chart of the loading impedance and impedance for the configurations of FIGS. 1 and 6 when processing example 4G signals;

FIG. 8a is an example plot of insertion loss over signal frequency for the configurations of FIGS. 1 and 6 when processing example 2G signals;

FIG. 8b is an example plot of insertion loss over signal frequency for the configurations of FIGS. 1 and 6 when processing example 4G signals;

FIG. 9 is an example block diagram of a front-end module for a radio frequency communications device having a secondary coil multi switching balun;

FIG. 10 is a die implemented in a packaged module having one or more features according to aspects of the present disclosure; and

FIG. 11 is a schematic block diagram of one example of a wireless communication device that includes a radio frequency circuit assembly according to aspects of the present invention.

### DETAILED DESCRIPTION

Aspects and embodiments described herein are directed to a radio frequency circuit assembly for a converged power amplifier where the radio frequency circuit assembly includes a transformer that is switchable between a respective configurations having different turn ratios.

This provides a switching transformer that can be designed into the overall front-end module configuration such that the circuits can be optimized for a plurality of different frequency bands (at the same power level, or at different power levels) while utilizing a converged power amplifier. This can enable a load line contour to be optimized for the plurality of different frequency bands, while also enabling a corresponding output matching network to be simplified and lower insertion losses and mismatch losses can be achieved.

It is to be appreciated that embodiments of the methods and apparatuses discussed herein are not limited in application to the details of construction and the arrangement of components set forth in the following description or illustrated in the accompanying drawings. The methods and apparatuses are capable of implementation in other embodiments and of being practiced or of being carried out in various ways. Examples of specific implementations are provided herein for illustrative purposes only and are not intended to be limiting. Also, the phraseology and terminology used herein is for the purpose of description and should not be regarded as limiting. The use herein of “including,” “comprising,” “having,” “containing,” “involving,” and variations thereof is meant to encompass the items listed thereafter and equivalents thereof as well as additional items. References to “or” may be construed as inclusive so that any terms described using “or” may indicate any of a single, more than one, and all of the described terms.

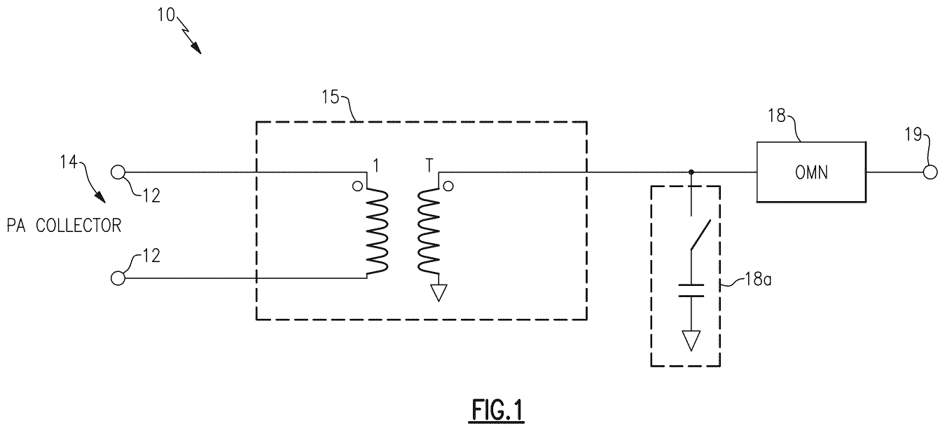

Radio frequency front end-modules typically involve a power amplifier and an antenna contact coupled by a radio frequency circuit, which may in turn include a transformer. Front-end modules may utilize a single power amplifier for amplifying radio frequency (RF) signals to be transmitted at a plurality of different RF bands (either at the same power level, or at different power levels), which may be referred to as a converged power amplifier. For example, the converged power amplifier may be configured to amplify RF signals including, but not limited to, two or more of 2G signals, 3G signals, 4G signals (including LTE, LTE-Advanced, and/or LTE-Advanced Pro), 5G NR signals, high medium band (HMB) signal, ultra high band (UHB) signals, etc. An example block diagram of a front-end module 10 for a radio frequency communications device including such a radio frequency circuit assembly is illustrated in FIG. 1. The example front-end module 10 comprises signal contacts 12, a power amplifier 14, transformer 15, output matching network 18, additional output matching network 18a, and an antenna contact 19.

The signal contacts 12 may be configured to receive RF signals that have been amplified by the power amplifier 14 and to pass these amplified RF signals to the transformer 15 to energize the primary coil of the transformer 15. The secondary coil of the transformer 15 may then be energized by coupling to the primary coil, and the resulting amplified RF signals passed to the output matching network 18 and output at the load of the antenna contact 19. The power amplifier may be configured to operate in a broadband mode, amplifying RF signals corresponding to a plurality of different RF frequency bands/ranges for transmission via the antenna contact 19 and a corresponding antenna assembly. Such a converged power amplifier for amplifying RF signals of a plurality of different frequency bands advantageously reduces the module area required for the front-end module (in comparison to using a separate power amplifier per RF frequency band). This is turn enables multi-chip-modules having a much smaller and compact size. However, the load line targets for respective RF frequency bands may be quite different due to differing saturated output power (PSAT), power-added efficiency (PAE), and other performance targets for each signals at each of the RF frequency bands. As an example, it has been found that it is difficult to balance and optimize the load line targets of both 2G and 4G RF signals, even when an additional output matching network 18a is switchably connected to the circuit and matching network to reduce the impedance for the processing of 2G RF signals for example.

Optimizing PSAT and PAE allows high-efficiency and enables low heat dissipation to be achieved in the front-end module; however, it is challenging to achieve acceptable load line targets for both 2G and 4G signals. In order to achieve good performance for a plurality of different RF frequency bands (such as 2G, 4G, MHB, and UHB RF signals) when using a single power amplifier, a new approach is needed to enable optimized load line characteristics for respective RF frequency bands without undesirable trade-off of the power output and performance at the respective RF frequency bands.

The present inventors have appreciated that the balun transformer for the power amplifier's output matching network may impact the above characteristics and that the PSAT and PAE for a 2G RF signal can be improved by increasing the balun transformer turn ratio; however, this would come at the cost of degrading the corresponding 4G performance. Correspondingly the PSAT and PAE for a 4G RF signal can be improved by decreasing the balun transformer turn ratio; however, this would come at the cost of degrading the corresponding 2G performance.

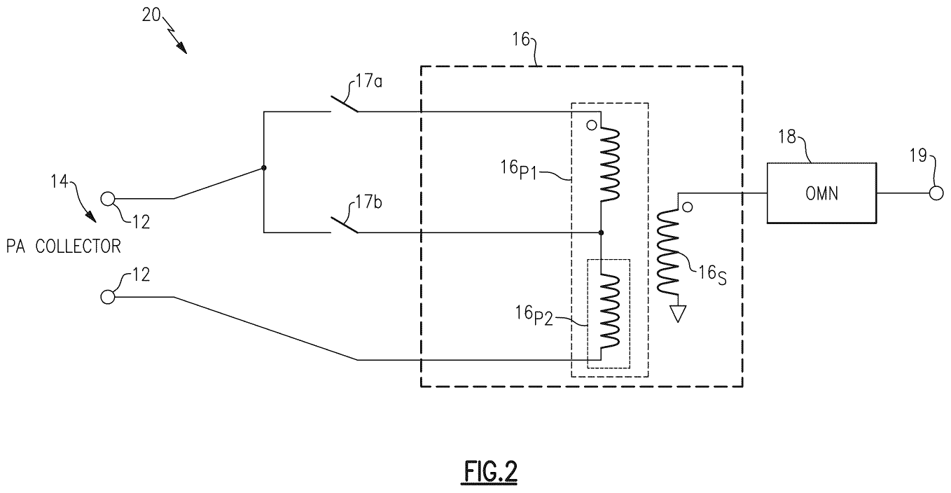

An example front-end module 20 using an improved radio frequency assembly is shown for a transmit path in FIG. 2. While the following discussion will focus on this example of a transmit path, it will be appreciated that the following teaching may also be applied to a receive path in a radio frequency circuit assembly for a front-end module. In the case of a receive path, the power amplifier 14 would be replaced by a low noise amplifier LNA and the signal contact 12 would be receive contact for the signal received by the antenna assembly coupled to the antenna contact 19.

Using common reference numerals where appropriate, the front-end module 20 of FIG. 2 comprises signal contacts 12, a power amplifier 14, transformer 16, switches 17a and 17b, output matching network 18, and an antenna contact 19. The transformer 16 of FIG. 2 comprises primary coils 16P1 and 16P2, and a secondary coil 16S. The signal contacts 12 receive RF signals that have been amplified by the power amplifier 14 and to pass these amplified RF signals to the transformer 16 via one of the switches 17a, 17b. If switch 17a is closed and switch 17b is open, then the amplified RF signals will energize the primary coil 16P1 of the transformer 16. Alternatively, if switch 17a is open and switch 17b is closed, then the amplified RF signals will energize the primary coil 16P2 of the transformer 16. The secondary coil 16S of the transformer 16 may then be energized by coupling to the primary coil (either 16P1 or 16P2), and the resulting amplified RF signals passed to the output matching network 18 for output at the load of the antenna contact 19.

Accordingly, the radio frequency circuit assembly of the front-end module 20 of FIG. 2 implements a switchable balun transformer 16 that has a differing primary inductance and turn ratio depending on whether primary coil 16P1 or primary coil 16P2 of the transformer 16 is coupled to the power amplifier 14 via one of the switches 17a, 17b. This enables the secondary coil 16S and the output matching network 18 to be maintained the same and simplified for both configurations. Specifically, the additional output matching network 18a of FIG. 1 is no longer required to adapt the circuit impedance to improve the performance for one of the RF frequency bands to be processed. It will be appreciated that the switches 17a, 17b could be implemented by a single double throw switch to selectively couple the power amplifier 14 to either the primary coil 16P1 or the primary coil 16P2.

As shown in FIG. 2, the transformer 16 may include two physical primary coils whereby switch 17b selectively connects one of the physical primary coils to the power amplifier 14 as a primary coil 16P2, and switch 17a selectively connects the two physical primary coils in series to form an aggregate primary coil 1 6P1 that is connected to the power amplifier 14. These configurations may also be embodied by implementing a single primary coil that is connected at one end to the power amplifier 14 via switch 17a to provide primary coil 16P1, and a coil tap connecting the power amplifier 14 to a point part way along the primary coil via switch 17b such that a portion of the primary coil is bypassed to provide the primary coil 16P2 having fewer turns than primary coil 16P1. By using one or more switches to selectively connect the power amplifier 14 to differing coil taps of the primary coil, a differing turn ratio can be provided for the transformer 16. These respective turn ratios can then be optimized for the respective load line targets of the two different RF frequency bands that the front-end module is configured to process. It will be appreciated that the primary coil 16P1 will correspond to a first primary impedance, while the primary coil 16P2 will correspond to a second primary impedance, where the first primary impedance is higher than the second primary impedance.

In one example, the front-end module 20 may be configured to process both 2G and 4G RF signals. For processing 4G RF signals, the front-end module may be switched into a configuration where switch 17a is closed and switch 17b is open such that primary coil 16P1 is utilized in the transformer 16. Alternatively, for processing 2G RF signals, the front-end module may be switched into a configuration where switch 17a is open and switch 17b is closed such that primary coil 16P2 is utilized in the transformer 16 to provide a comparatively higher turn ratio.

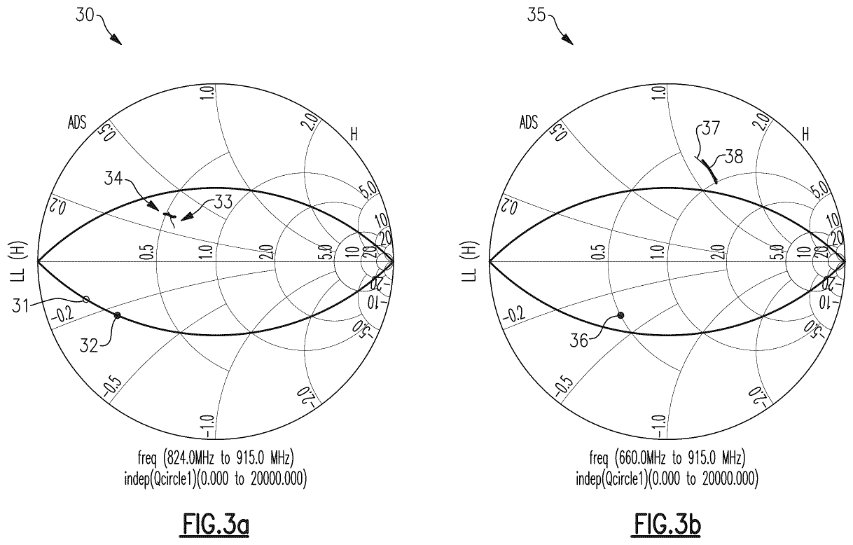

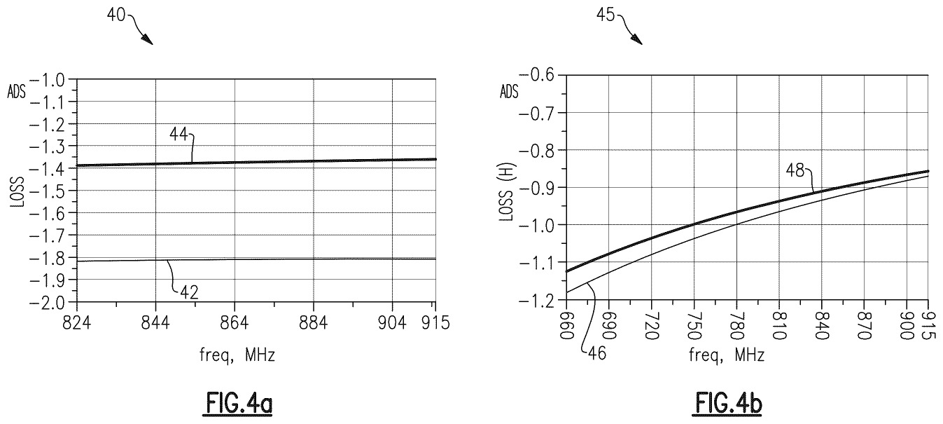

In this manner, the inventors have appreciated that this configuration can be tuned to achieve optimum performance for the processing of both 2G and 4G RF signals. Specifically, the performance for both 2G and 4G signals can be enhanced through optimized load line contour as shown in the comparison of FIGS. 3a and 3b, and through reduced insertion losses as shown in the comparison of FIGS. 4a and 4b without compromising either the load line contour or the insertion loss.

FIG. 3a is an example smith chart 30 of the loading impedance and impedance for the configurations of FIGS. 1 and 2 when processing example 2G signals, and FIG. 3b is an example smith chart 35 of the loading impedance and impedance for the configurations of FIGS. 1 and 2 when processing example 4G signals.

In FIG. 3a, point 31 represents the impedance at the output of the balun transformer 15 for an example configuration according to FIG. 1, while point 32 represents the impedance at the output of the balun transformer 16 for an example primary coil switching balun transformer configuration according to FIG. 2. It can be seen that the impedance for 2G performance has been improved in the switching balun transformer configuration of FIG. 2. Point 33 of FIG. 3a represents the loading impedance at the power amplifier collector for the example configuration according to FIG. 1, while point 34 represents the loading impedance at the power amplifier collector for the example switching balun transformer configuration according to FIG. 2. It can be seen that the bandwidth of the loading impedance for 2G performance has been improved by about 10% in the example switching balun transformer configuration 16.

In FIG. 3b, point 36 represents the impedance at the output of the balun transformer for both an example configuration according to FIG. 1 and an example switching balun transformer configuration 16 according to FIG. 2. Accordingly, it can be seen that the impedance for 4G performance has not been sacrificed by the improvements in the 2G performance when implementing the switching balun transformer configuration of FIG. 2. Point 37 of FIG. 3b represents the loading impedance at the power amplifier collector for the example configuration according to FIG. 1, while point 38 represents the loading impedance at the power amplifier collector for the example switching balun transformer configuration according to FIG. 2. It can be seen that the bandwidth of the loading impedance for 4G performance has also been improved by about 5% in the example switching balun transformer configuration 16.

FIG. 4a is an example plot 40 of the insertion loss in dB over signal frequency for the balun transformer 15, 16 and the output matching network 18 for the respective configurations of FIGS. 1 and 2 when processing example 2G signals. Plot 42 represents the insertion loss for 2G signals for the example configuration according to FIG. 1, and plot 44 represents the insertion loss for 2G signals for the example switching balun transformer configuration according to FIG. 2. As can be seen, the example switching balun transformer configuration 16 improves the insertion losses for 2G signals by approximately 0.45 dB. This may also improve the PAE by approximately 4% or 5%. These improvements may be attributed, in part, to the simplification of the output matching network 18 by the omission of the additional output matching network 18a.

FIG. 4b is an example plot 45 of the insertion loss in dB over signal frequency for the balun transformer 15, 16 and the output matching network 18 for the respective configurations of FIGS. 1 and 2 when processing example 4G signals. Plot 46 represents the insertion loss for 4G signals for the example configuration according to FIG. 1, and plot 48 represents the insertion loss for 4G signals for the example switching balun transformer configuration according to FIG. 2. As can be seen, the example primary coil switching balun transformer configuration 16 also improves the insertion losses for 4G signals, in this example by approximately 0.06 dB.

The primary coil switching balun transformer configuration 16 improves the flexibility of the loading impedance at the output of the balun transformer due to the switchable turn ratio that is provided, which enables the output matching network to be simplified and the mismatch loss to be reduced.

In some embodiments, it may be desirable for the radio frequency circuit assembly and front-end module to be configured to process more than two different RF frequency bands. It will be appreciated that the configuration of FIG. 2 can easily be extended to accommodate n frequency bands by introducing additional coil taps and switching paths for the primary coil to provide n different transformer configurations having different turn ratios.

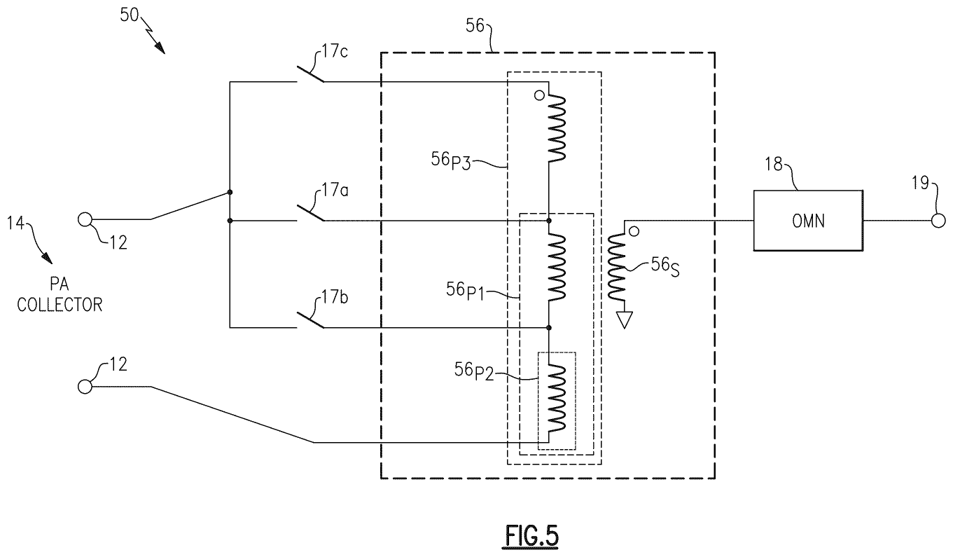

FIG. 5 illustrates an example front-end module 50 having three different switchable paths. The front-end module 50 of FIG. 5 comprises signal contacts 12, a power amplifier 14, a transformer 56, switches 17a, 17b, and 17c, an output matching network 18, and an antenna contact 19. The transformer 56 of FIG. 5 comprises primary coils 56P1, 56P2, and 56P3, and a secondary coil 56S. The signal contacts 12 receive RF signals that have been amplified by the power amplifier 14 and to pass these amplified RF signals to the transformer 56 via one of the switches 17a, 17b, and 17c. If switch 17a is closed and switches 17b and 17c are open, then the amplified RF signals will energize the primary coil 56P1 of the transformer 56. Alternatively, if switch 17b is closed and switches 17a and 17c are open, then the amplified RF signals will energize the primary coil 56P2 of the transformer 56. Alternatively, if switch 17c is closed and switches 17a and 17b are open, then the amplified RF signals will energize the primary coil 56P3 of the transformer 56. The secondary coil 56S of the transformer 56 may then be energized by coupling to the primary coil (either 56P1, 56P2, or 56P3), and the resulting amplified RF signals passed to the output matching network 18 for output at the load of the antenna contact 19.

Accordingly, the radio frequency circuit assembly of the front-end module 50 of FIG. 5 implements a primary coil switchable balun transformer 56 that has a differing primary inductance and turn ratio depending on whether primary coil 56P1, primary coil 56P2, or primary coil 56P3 of the transformer 56 is coupled to the power amplifier 14 via one of the switches 17a, 17b, or 17c. In one example, the use of primary coil 56P1 may be configured for processing 4G signals, the use of primary coil 56P2 may be configured for processing 2G signals, and the use of primary coil 56P3 may be configured for processing RF signals in the MHB, UHB, or other RF frequency bands. In this manner, the 2G configuration may utilize a turn ratio that is higher than that for the 4G configuration, while the MHB/UHB/other configuration utilize a turn ratio that is lower than that for the 4G configuration. It will be appreciated that the above discussion in relation to FIGS. 2 to 4 also applies to the configuration of FIG. 5.

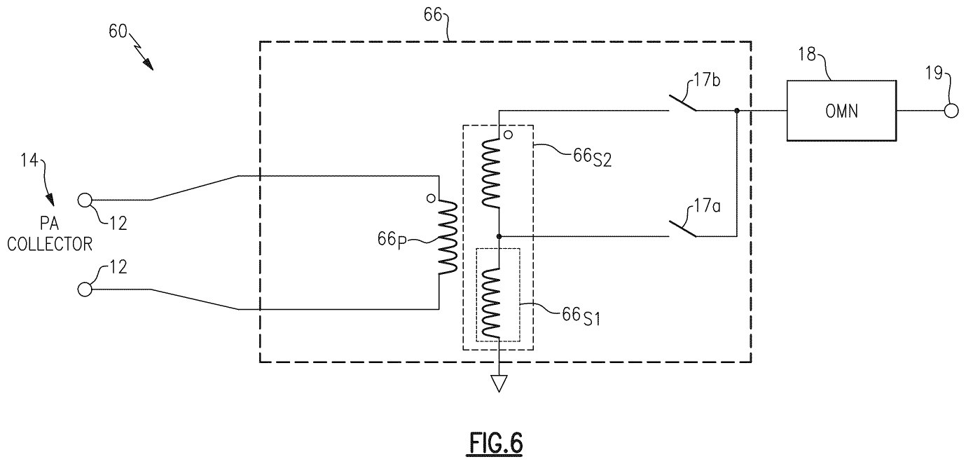

In the above embodiments, the switching of the transformer 16, 56 has been implemented for the primary coil. The inventors have appreciated that this switching could also be implemented for the secondary coil as shown in the example of FIG. 6.

Using common reference numerals where appropriate, the front-end module 60 of FIG. 6 comprises signal contacts 12, a power amplifier 14, transformer 66, switches 17a and 17b, output matching network 18, and an antenna contact 19. The transformer 66 of FIG. 6 comprises a primary coil 66P, and secondary coils 66S1 and 66S2. The signal contacts 12 receive RF signals that have been amplified by the power amplifier 14 and to pass these amplified RF signals to energize the primary coil 66P of the transformer 66. One of the secondary coils 66S1 or 66S2 may then be energized by coupling to the primary coil 66P depending on which of the secondary coils 66S1 and 66S2 are coupled to the load of the antenna contact 19 and output matching network 18 via one of the switches 17a, 17b. If switch 17a is closed and switch 17b is open, then the primary coil 66P will energize the secondary coil 66S1 of the transformer 66. Alternatively, if switch 17a is open and switch 17b is closed, then the primary coil 66P will energize the secondary coil 66S2 of the transformer 66. The resulting amplified RF signals may then be passed to the output matching network 18 for output at the antenna contact 19 load.

Accordingly, the radio frequency circuit assembly of the front-end module 60 of FIG. 6 implements a switchable balun transformer 66 that has a differing secondary inductance and turn ratio depending on whether secondary coil 66S1 or secondary coil 66S2 of the transformer 66 is coupled to the load of the antenna contact 19 and output matching network 18 via one of the switches 17a, 17b. This enables the primary coil 16P and the output matching network 18 to be maintained the same and simplified for both configurations. Specifically, the additional output matching network 18a of FIG. 1 is no longer required to adapt the circuit impedance to improve the performance for one of the RF frequency bands to be processed. It will be appreciated that the switches 17a, 17b could be implemented by a single double throw switch to selectively couple the load of the antenna contact 19 and output matching network 18 to either the secondary coil 66S1 or the secondary coil 66S2.

As shown in FIG. 6, the transformer 66 may include two physical secondary coils whereby switch 17a selectively connects one of the physical secondary coils to the antenna contact 19 and output matching network 18 as a secondary coil 66S1, and switch 17b selectively connects the two physical secondary coils in series to form a secondary coil 66S2 that is connected to the antenna contact 19 and output matching network 18. These configurations may also be embodied by implementing a single secondary coil that is connected at one end to the output matching network 18 and antenna contact 19 via switch 17b to provide secondary coil 66S2, and a coil tap connecting the output matching network 18 and antenna contact 19 to a point part way along the secondary coil via switch 17a such that a portion of the secondary coil is bypassed to provide the secondary coil 66S1 having fewer turns than secondary coil 66S2. By using one or more switches to selectively connect the output matching network 18 and antenna contact 19 to differing coil taps of the secondary coil, a differing turn ratio can be provided for the transformer 66. These respective turn ratios can then be optimized for the respective load line targets of the two different RF frequency bands that the front-end module 60 is configured to process. It will be appreciated that the secondary coil 66S1 will correspond to a first secondary impedance, while the secondary coil 66S2 will correspond to a second secondary impedance that is higher than the first secondary impedance.

In one example, the front-end module 60 may be configured to process both 2G and 4G RF signals. For processing 4G RF signals, the front-end module 60 may be switched into a configuration where switch 17a is closed and switch 17b is open such that secondary coil 66S1 is utilized in the transformer 66. Alternatively, for processing 2G RF signals, the front-end module may be switched into a configuration where switch 17a is open and switch 17b is closed such that secondary coil 66S2 is utilized in the transformer 66 to provide a comparatively higher turn ratio.

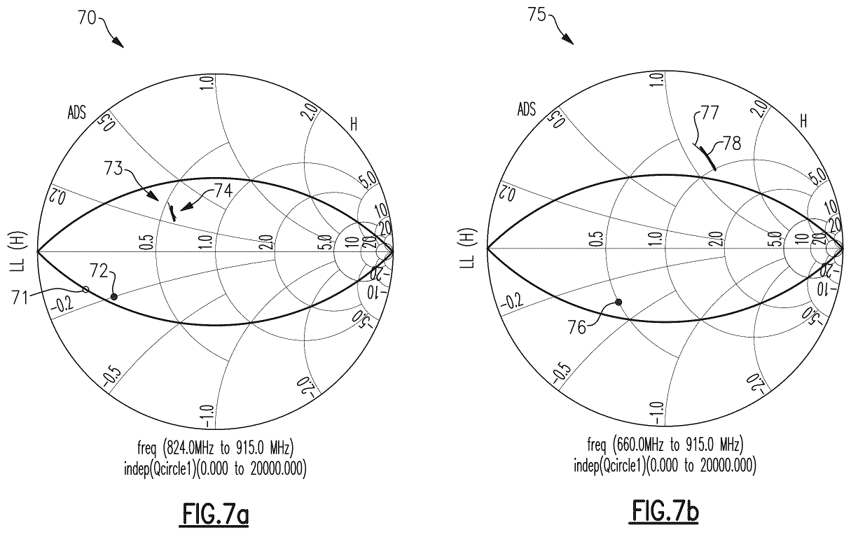

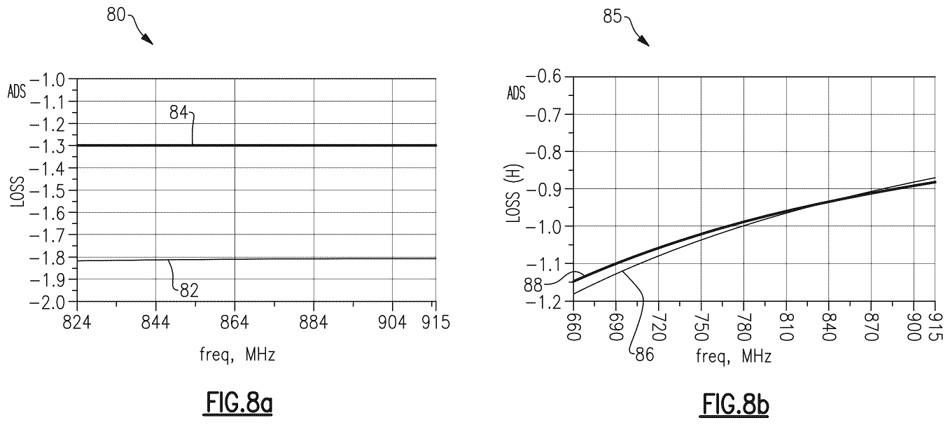

In this manner, the inventors have appreciated that this configuration can be tuned to achieve optimum performance for the processing of both 2G and 4G RF signals. Specifically, the performance for both 2G and 4G signals can be enhanced through optimized load line contour as shown in the comparison of FIGS. 7a and 7b, and through reduced insertion losses as shown in the comparison of FIGS. 8a and 8b without compromising either the load line contour or the insertion loss.

FIG. 7a is an example smith chart 70 of the loading impedance and impedance for the configurations of FIGS. 1 and 6 when processing example 2G signals, and FIG. 7b is an example smith chart 75 of the loading impedance and impedance for the configurations of FIGS. 1 and 6 when processing example 4G signals.

In FIG. 7a, point 71 represents the impedance at the output of the balun transformer 15 for an example configuration according to FIG. 1, while point 72 represents the impedance at the output of the balun transformer 66 for an example secondary coil switching balun transformer configuration according to FIG. 6. It can be seen that the impedance for 2G performance has been improved in the switching balun transformer configuration of FIG. 6. Point 73 of FIG. 7a represents the loading impedance at the power amplifier collector for the example configuration according to FIG. 1, while point 74 represents the loading impedance at the power amplifier collector for the example switching balun transformer configuration according to FIG. 6. It can be seen that the bandwidth of the loading impedance for 2G performance has been improved by about 6% in the example secondary coil switching balun transformer configuration.

In FIG. 7b, point 76 represents the impedance at the output of the balun transformer 15, 66 for both an example configuration according to FIG. 1 and an example switching balun transformer configuration according to FIG. 6. Accordingly, it can be seen that the impedance for 4G performance has not been sacrificed by the improvements in the 2G performance when implementing the switching balun transformer configuration 66 of FIG. 6. Point 77 of FIG. 7b represents the loading impedance at the power amplifier collector for the example configuration according to FIG. 1, while point 78 represents the loading impedance at the power amplifier collector for the example switching balun transformer configuration 66 according to FIG. 6. It can be seen that the bandwidth of the loading impedance for 4G performance has also been improved by about 6% in the example switching balun transformer configuration.

FIG. 8a is an example plot 80 of the insertion loss in dB over signal frequency for the balun transformer 15, 66 and the output matching network 18 for the respective configurations of FIGS. 1 and 6 when processing example 2G signals. Plot 82 represents the insertion loss for 2G signals for the example configuration according to FIG. 1, and plot 84 represents the insertion loss for 2G signals for the example switching balun transformer configuration 66 according to FIG. 6. As can be seen, the example switching balun transformer configuration 66 improves the insertion losses for 2G signals by approximately 0.5 dB. This may also improve the PAE by approximately 4% or 5%. These improvements may be attributed, in part, to the simplification of the output matching network 18 by the omission of the additional output matching network 18a.

FIG. 8b is an example plot 85 of the insertion loss in dB over signal frequency for the balun transformer 15, 66 and the output matching network 18 for the respective configurations of FIGS. 1 and 6 when processing example 4G signals. Plot 86 represents the insertion loss for 4G signals for the example configuration according to FIG. 1, and plot 88 represents the insertion loss for 4G signals for the example secondary coil switching balun transformer configuration 66 according to FIG. 6. As can be seen, the example secondary coil switching balun transformer configuration 66 also improves the insertion losses for 4G signals, in this example by approximately 0.04 dB.

The secondary coil switching balun transformer configuration 66 improves the flexibility of the loading impedance at the output of the balun transformer due to the switchable turn ratio that is provided, which enables the output matching network to be simplified and the mismatch loss to be reduced.

In some embodiments, it may be desirable for the radio frequency circuit assembly and front-end module to be configured to process more than two different RF frequency bands. It will be appreciated that the configuration of FIG. 6 can also be easily extended to accommodate n frequency bands by introducing additional coil taps and switching paths for the secondary coil to provide n different transformer configurations having different turn ratios.

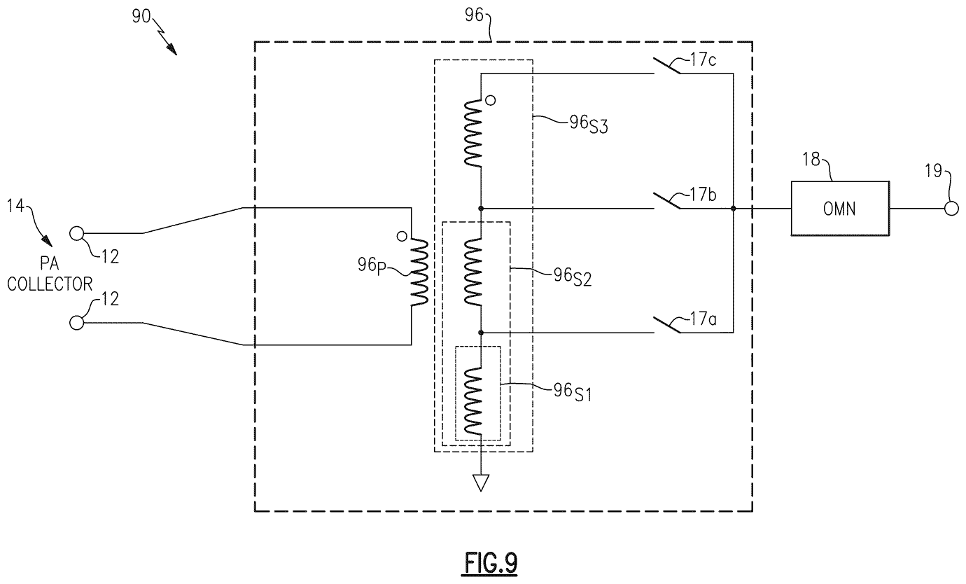

FIG. 9 illustrates an example front-end module 90 having three different switchable paths. The front-end module 90 of FIG. 9 comprises signal contacts 12, a power amplifier 14, a transformer 96, switches 17a, 17b, and 17c, an output matching network 18, and an antenna contact 19. The transformer 96 of FIG. 9 comprises a primary coil 96P and secondary coils 96S1, 96S2, and 96S3. The signal contacts 12 receive RF signals that have been amplified by the power amplifier 14 and to pass these amplified RF signals to energize the primary coil 96P of the transformer 96. One of the secondary coils 96S1, 96S2, or 96S3 may then be energized by coupling to the primary coil 96P depending on which of the secondary coils 96S1, 96S2, or 96S3 are coupled to the load of the antenna contact 19 and output matching network 18 via one of the switches 17a, 17b, and 17c.

If switch 17a is closed and switches 17b and 17c are open, then the primary coil 96P will energize the secondary coil 96S1 of the transformer 96. Alternatively, if switch 17b is closed and switches 17a and 17c are open, then the primary coil 96P will energize the secondary coil 96S2 of the transformer 96. Alternatively, if switch 17c is closed and switches 17a and 17b are open, then the primary coil 96P will energize the secondary coil 96S3 of the transformer 96. The resulting amplified RF signals may then be passed to the output matching network 18 for output at the antenna contact 19 load.

Accordingly, the radio frequency circuit assembly of the front-end module 90 of FIG. 9 implements a secondary coil switchable balun transformer 96 that has a differing secondary inductance and turn ratio depending on whether secondary coil 96S1, secondary coil 96S2, or secondary coil 96S3 of the transformer 96 is coupled to the load of the antenna contact 19 and output matching network 18 via one of the switches 17a, 17b, and 17c. In one example, the use of secondary coil 96S1 may be configured for processing 4G signals, the use of secondary coil 96S2 may be configured for processing 2G signals, and the use of secondary coil 96S3 may be configured for processing RF signals in the MHB, UHB, or other RF frequency bands. In this manner, the 2G configuration may utilize a turn ratio that is higher than that for the 4G configuration, while the MHB/UHB/other configuration utilize a turn ratio that is lower than that for the 4G configuration. It will be appreciated that the above discussion in relation to FIGS. 6 to 8 also applies to the configuration of FIG. 9.

Radio frequency circuit assemblies disclosed herein can be implemented in the front-end modules of wireless communication devices. The radio frequency circuit assemblies may be implemented in a discrete form with constituent discrete components (e.g. the power amplifier components, the acoustic filter components, the ASM, the LNA, switches, and/or the baluns) formed directly on the printed circuit board (PCB) of the wireless communication device. Alternatively, an integrated module, such as a multi-chip module (MCM), may include each of these components, with the components either being patterned directly into the MCM PCB, or attached via dies. The finished module may then be over molded for protection and packaging.

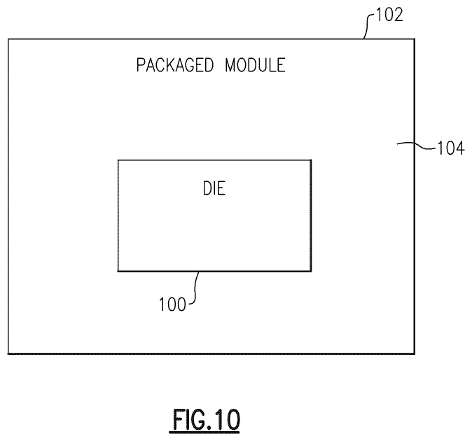

FIG. 10 is a die 100 implemented in a packaged module 102. Such a packaged module can include a packaging substrate 104 configured to receive a plurality of components. In one example, the packaging substrate may be configured to receive a radio frequency circuit assembly having one or more features described herein. In one example the packaged module 102 may be a front-end module. In some examples, the packaging substrate 104 may be configured to receive further components such as an RF power amplifier, one or more RF filters, and/or a low noise amplifier (LNA). The packaged module 102 may be implemented in a single-sided or double-sided molded package.

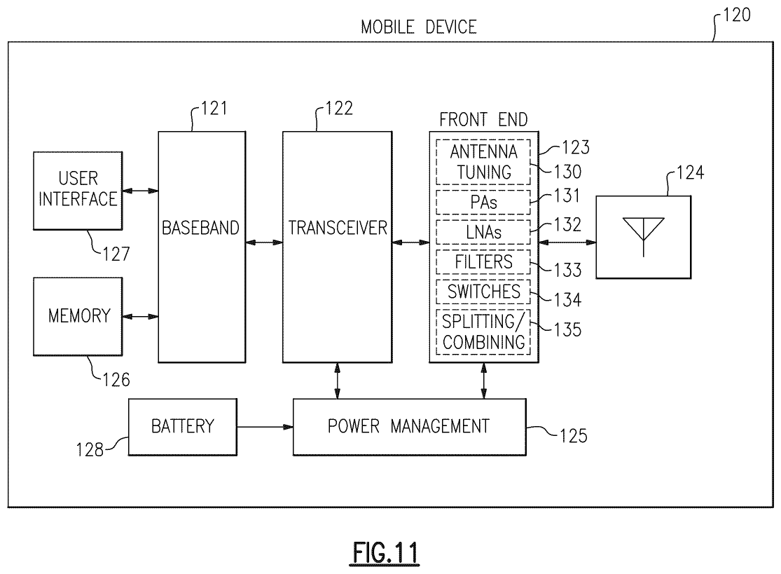

FIG. 11 is a schematic block diagram of a wireless communication device 120 that includes a radio frequency circuit assembly according to an embodiment. The wireless communication device 120 can be a mobile device. The wireless communication device 120 can be any suitable wireless communication device. For instance, a wireless communication device 120 can be a mobile phone, such as a smart phone. As illustrated, the wireless communication device 120 includes a baseband system 121, a transceiver 122, a front-end system 123, an antenna assembly having one or more antennas 124, a power management system 125, a memory 126, a user interface 127, and a battery 128.

The wireless communication device 120 can communicate using a wide variety of communications technologies, including, but not limited to, 2G, 3G, 4G (including LTE, LTE-Advanced, and/or LTE-Advanced Pro), 5G NR, WLAN (for instance, Wi-Fi), WPAN (for instance, Bluetooth and/or ZigBee), WMAN (for instance, WiMax), and/or GPS technologies.

The transceiver 122 generates RF signals for transmission and processes incoming RF signals received from the antennas 124. Various functionalities associated with the transmission and receiving of RF signals can be achieved by one or more components that are collectively represented in FIG. 11 as the transceiver 122. In one example, separate components (for instance, separate circuits or dies) can be provided for handling certain types of RF signals.

The front-end system 123 aids in conditioning signals provided to and/or received from the antennas 124. In the illustrated embodiment, the front-end system 123 includes antenna tuning circuitry 130, power amplifiers (PAs) 131, low noise amplifiers (LNAs) 132, filters 133, switches 134, and signal splitting/combining circuitry 135. However, other implementations are possible. The front-end system 123 can include one or more radio frequency circuit assemblies in accordance with any suitable principles and advantages disclosed herein. For example, the filters 133 may comprise differentially arranged band pass filters arranged within a radio frequency circuit assembly in accordance with any suitable principles and advantages disclosed herein.

The front-end system 123 can provide a number of functionalities, including, but not limited to, amplifying signals for transmission, amplifying received signals, filtering signals, switching between different bands, switching between different power modes, switching between transmission and receiving modes, duplexing of signals, multiplexing of signals, or any suitable combination thereof.

In certain implementations, the wireless communication device 120 supports carrier aggregation, thereby providing flexibility to increase peak data rates. Carrier aggregation can be used for Frequency Division Duplexing (FDD) and/or Time Division Duplexing (TDD), and may be used to aggregate a plurality of carriers and/or channels. Carrier aggregation includes contiguous aggregation, in which contiguous carriers within the same operating frequency band are aggregated. Carrier aggregation can also be non-contiguous, and can include carriers separated in frequency within a common band or in different bands.

The antennas 124 can include antennas used for a wide variety of types of communications. For example, the antennas 124 can include antennas for transmitting and/or receiving signals associated with a wide variety of frequencies and communications standards.

In certain implementations, the antennas 124 support MIMO communications and/or switched diversity communications. For example, MIMO communications use multiple antennas for communicating multiple data streams over a single radio frequency channel. MIMO communications benefit from higher signal to noise ratio, improved coding, and/or reduced signal interference due to spatial multiplexing differences of the radio environment. Switched diversity refers to communications in which a particular antenna is selected for operation at a particular time. For example, a switch can be used to select a particular antenna from a group of antennas based on a variety of factors, such as an observed bit error rate and/or a signal strength indicator.

The wireless communication device 120 can operate with beamforming in certain implementations. For example, the front-end system 123 can include amplifiers having controllable gain and phase shifters having controllable phase to provide beam formation and directivity for transmission and/or reception of signals using the antennas 124. For example, in the context of signal transmission, the amplitude and phases of the transmit signals provided to the antennas 124 are controlled such that radiated signals from the antennas 124 combine using constructive and destructive interference to generate an aggregate transmit signal exhibiting beam-like qualities with more signal strength propagating in a given direction. In the context of signal reception, the amplitude and phases are controlled such that more signal energy is received when the signal is arriving to the antennas 124 from a particular direction. In certain implementations, the antennas 124 include one or more arrays of antenna elements to enhance beamforming.

The baseband system 121 is coupled to the user interface 127 to facilitate processing of various user input and output (I/O), such as voice and data. The baseband system 121 provides the transceiver 122 with digital representations of transmit signals, which the transceiver 122 processes to generate RF signals for transmission. The baseband system 121 also processes digital representations of received signals provided by the transceiver 122. As shown in FIG. 11, the baseband system 121 is coupled to the memory 126 of facilitate operation of the wireless communication device 120.

The memory 126 can be used for a wide variety of purposes, such as storing data and/or instructions to facilitate the operation of the wireless communication device 120 and/or to provide storage of user information.

The power management system 125 provides a number of power management functions of the wireless communication device 120. In certain implementations, the power management system 125 includes a power amplifier supply control circuit that controls the supply voltages of the power amplifiers 131. For example, the power management system 125 can be configured to change the supply voltage(s) provided to one or more of the power amplifiers 131 to improve efficiency, such as power added efficiency (PAE).

As shown in FIG. 11, the power management system 125 receives a battery voltage from the battery 128. The battery 128 can be any suitable battery for use in the wireless communication device 120, including, for example, a lithium-ion battery.

Any of the embodiments described above can be implemented in association with mobile devices such as cellular handsets. The principles and advantages of the embodiments can be used for any systems or apparatus, such as any uplink wireless communication device, that could benefit from any of the embodiments described herein. The teachings herein are applicable to a variety of systems. Although this disclosure includes example embodiments, the teachings described herein can be applied to a variety of structures. Any of the principles and advantages discussed herein can be implemented in association with RF circuits configured to process signals having a frequency in a range from about 30 kHz to 300 GHz, such as in a frequency range from about 400 MHz to 8.5 GHz or in a frequency range from about 400 MHz to 5 GHz.

Aspects of this disclosure can be implemented in various electronic devices. Examples of the electronic devices can include, but are not limited to, consumer electronic products, parts of the consumer electronic products such as packaged radio frequency modules, uplink wireless communication devices, wireless communication infrastructure, electronic test equipment, etc. Examples of the electronic devices can include, but are not limited to, a mobile phone such as a smart phone, a wearable computing device such as a smart watch or an ear piece, a telephone, a television, a computer monitor, a computer, a modem, a hand-held computer, a laptop computer, a tablet computer, a microwave, a refrigerator, a vehicular electronics system such as an automotive electronics system, a robot such as an industrial robot, an Internet of things device, a stereo system, a digital music player, a radio, a camera such as a digital camera, a portable memory chip, a home appliance such as a washer or a dryer, a peripheral device, a wrist watch, a clock, etc. Further, the electronic devices can include unfinished products.

Conditional language used herein, such as, among others, “can,” “could,” “might,” “may,” “e.g.,” “for example”, “such as” and the like, unless specifically stated otherwise, or otherwise understood within the context as used, is generally intended to convey that certain embodiments include, while other embodiments do not include, certain features, elements and/or states. The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively.

The examples shown in FIGS. 2 to 9 are intended to be functional illustrations and not limiting in any aspect with respect to actual implementations of the radio frequency circuit assembly or front-end module. Aspects and embodiments provide a switching balun transformer that can be designed into the overall front-end module configuration such that the circuits can be optimized for a plurality of different frequency bands while utilizing a converged power amplifier. This can enable a load line contour to be optimized for the plurality of different frequency bands. This can enable a corresponding output matching network to be simplified and lower insertion losses and mismatch losses can be achieved.

While certain embodiments have been described, these embodiments have been presented by way of example only, and are not intended to limit the scope of the disclosure. Indeed, the novel resonators, filters, modules, devices, wireless communication devices, apparatus, and systems described herein may be embodied in a variety of other forms. Furthermore, various omissions, substitutions and changes in the form of the resonators, filters, modules, devices, wireless communication devices, apparatus, and systems described herein may be made without departing from the spirit of the disclosure. For example, while blocks are presented in a given arrangement, alternative embodiments may perform similar functionalities with different components and/or circuit topologies, and some blocks may be deleted, moved, added, subdivided, combined, and/or modified. Each of these blocks may be implemented in a variety of different ways. Any suitable combination of the elements and/or acts of the various embodiments described above can be combined to provide further embodiments. Accordingly, the foregoing description and drawings are by way of example only, and the scope of the invention should be determined from proper construction of the appended claims, and their equivalents.

1. A radio frequency circuit assembly, comprising:
a signal contact configured to receive amplified signals, the amplified signals including amplified signals of a first frequency band and amplified signals of a second frequency band;
an antenna contact; and
a transformer connected in a signal path between the signal contact and the antenna contact, the transformer being switchable between a first configuration and a second configuration, the first configuration having a different turn ratio than the second configuration.

2. The radio frequency circuit assembly of claim 1 further comprising one or more switches coupled to a primary coil of the transformer, the one or more switches being configured to switch the transformer between the first configuration and the second configuration, and the one or more switches being configured to alter a number of turns in the primary coil that are coupled to the signal contact.

3. The radio frequency circuit assembly of claim 2 wherein the one or more switches are coupled to one or more coil taps of the transformer to alter a number of turns in the coil.

4. The radio frequency circuit assembly of claim 2 wherein the one or more switches are configured to alter the number of turns in the coil by selectively connecting a plurality of coils in series to form the primary coil of the transformer.

5. The radio frequency circuit assembly of claim 1 further comprising one or more switches coupled to a secondary coil of the transformer, the one or more switches being configured to switch the transformer between the first configuration and the second configuration, and the one or more switches being configured to alter a number of turns in the secondary coil that are coupled to the antenna contact.

6. The radio frequency circuit assembly of claim 5 wherein the one or more switches are coupled to one or more coil taps of the transformer to alter the number of turns in the coil.

7. The radio frequency circuit assembly of claim 5 wherein the one or more switches are configured to alter the number of turns in the coil by selectively connecting a plurality of coils in series to form the secondary coil of the transformer.

8. The radio frequency circuit assembly of claim 1 further comprising an output matching network that is tuned for the amplified signals of both the first frequency band and the second frequency band.

9. The radio frequency circuit assembly of claim 1 wherein the transformer is switchable between three or more different configurations, each configuration having a different turn ratio than other configurations of the three or more different configurations.

10. A front-end module, comprising:
a power amplifier configured to amplify signals of a first frequency band and signals of a second frequency band;
an antenna contact; and
a transformer connected in a signal path between the power amplifier and the antenna contact, the transformer being switchable between a first configuration and a second configuration, the first configuration having a different turn ratio than the second configuration.

11. The front-end module of claim 10 further comprising one or more switches coupled to a primary coil of the transformer, the one or more switches being configured to switch the transformer between the first configuration and the second configuration, and the one or more switches being configured to alter a number of turns in the primary coil that are coupled to the power amplifier.

12. The front-end module of claim 11 wherein the one or more switches are coupled to one or more coil taps of the transformer to alter the number of turns in the coil.

13. The front-end module of claim 11 wherein the one or more switches are configured to alter the number of turns in the coil by selectively connecting a plurality of coils in series to form the primary coil of the transformer.

14. The front-end module of claim 10 further comprising one or more switches coupled to a secondary coil of the transformer, the one or more switches being configured to switch the transformer between the first configuration and the second configuration, and the one or more switches being configured to alter a number of turns in the secondary coil that are coupled to the antenna contact.

15. The front-end module of claim 14 wherein the one or more switches are coupled to one or more coil taps of the transformer to alter the number of turns in the coil.

16. The front-end module of claim 14 wherein the one or more switches are configured to alter a number of turns in the coil by selectively connecting a plurality of coils in series to form the secondary coil of the transformer.

17. The front-end module of claim 10 further comprising an output matching network that is tuned for the amplified signals of both the first frequency band and the second frequency band.

18. The front-end module of claim 10 wherein the transformer is switchable between three or more different configurations, each configuration having a different turn ratio than other configurations of the three or more different configurations.

19. The front-end module of claim 10 wherein the power amplifier is a low noise amplifier, the signal path is a receive path, and further comprising a signal contact in the receive path.

20. A wireless communication device comprising:
an antenna assembly configured to receive and/or transmit radio frequency signals at both a first frequency band and a second frequency band;
a power amplifier configured to amplify signals of the first frequency band and signals of the second frequency band; and
a transformer connected in a signal path between the power amplifier and the antenna assembly, the transformer being switchable between a first configuration and a second configuration, the first configuration having a different turn ratio than the second configuration.
